(19) United States
(12) Patent Application Publication
(10) Pub. No.: US 2017/0275761 A1
(43) Pub. Date: Sep. 28, 2017

(54) PLASMA PROCESSING APPARATUS

(71) Applicant: Shibaura Mechatronics Corporation, Yokohama-shi (JP)

(72) Inventor: Yoshinao Kamo, Yokohama-shi (JP)

(21) Appl. No.: 15/467,602

(22) Filed: Mar. 23, 2017

(30) Foreign Application Priority Data
Mar. 25, 2016 (JP) 2016-061509

(51) Int. Cl. C23C 16/50; H01J 37/32; C23C 16/458

(52) U.S. Cl. CPC C23C 16/50; C23C 16/458; H01J 37/32082; H01J 37/32651; H01J 37/32532; H01J 2237/334

(57) ABSTRACT

A plasma processing apparatus includes a cylindrical electrode which has a lower end provided with an opening, an upper end that is a closed end, in which a process gas is introduced, and which obtains a plasma process gas upon application of the voltage, and a chamber that is a vacuum container provided with an opening. The cylindrical electrode, which has the upper end attached to the opening of the chamber via an insulation material, is extended in the chamber. The plasma processing apparatus also includes a rotation table carrying a workpiece to be processed by the process gas to a space below the opening of the cylindrical electrode, a shield covering the cylindrical electrode extended inside the chamber via a gap, and a spacer installed in the gap, and formed of an insulation material.

### CROSS-REFERENCE TO RELATED APPLICATION

This application is based upon and claims the benefit of priority from Japan Patent Application No. 2016-061509, filed on Mar. 25, 2016, the entire contents of which are incorporated herein by reference.

### FIELD OF THE INVENTION

The present disclosure relates to a plasma processing apparatus.

### BACKGROUND

In manufacturing of various products, such as a semiconductor element, a liquid crystal display, and an optical disk, a thin film like an optical film is formed on a workpiece, such as a wafer or a glass substrate. This thin film is formed by, for example, film formation process of forming a metal film, etc., on the workpiece, and film treatment process like etching, oxidization or nitridation to the formed film.

Film formation and film treatment process can be performed in various schemes, and an example scheme is to apply plasma. In film formation, an inactive gas is introduced in a chamber in which a target is placed, and a DC voltage is applied to the target to obtain the plasma inactive gas. Ions of the plasma inactive gas are caused to collide with the target, and material particles beaten out from the target are deposited on a workpiece to form a film. In film treatment process, a process gas is introduced in a chamber in which an electrode is placed, and a high-frequency voltage is applied to the electrode to obtain the plasma process gas. Ions of the plasma process gas are caused to collide with the film on the workpiece, and the film treatment process is carried out.

In order to enable a sequential execution of such film formation and film treatment process, JP 2002-256428 A discloses a plasma processing apparatus which has a rotation table installed in a chamber, and also has a plurality of film formation units and film treatment process units installed above the circumferential direction of the rotation table. A workpiece is held on the rotation table and carried so as to pass through the spaces right below the film formation unit and the film treatment process unit, and thus an optical film, etc., is formed.

Some plasma processing apparatuses that have the rotation table utilize a film treatment process unit that is a cylindrical electrode which has a closed upper end and has an opened lower end. When the cylindrical electrode is utilized, an opening is provided in the upper part of the chamber, and the upper end of the cylindrical electrode is attached to this opening via an insulation member. A side wall of the cylindrical electrode extends inside the chamber, and the opened lower end of the cylindrical electrode faces the rotation table via a slight gap. The chamber is grounded, and the cylindrical electrode serves as an anode, while the chamber and the rotation table serve as a cathode. The process gas is introduced in the cylindrical electrode, and the high-frequency voltage is applied to obtain plasma. Electrons contained in the obtained plasma flow into the cathode that is the rotation table. By causing the workpiece held by the rotation table to pass through the space right below the opened lower end of the cylindrical electrode, ions contained in the plasma collide with the workpiece, and thus film treatment process is executed.

A cylindrical shield is attached to the chamber so as to cover the side wall of the cylindrical electrode extended in the chamber. The shield is attached to the circumference edge of the opening of the chamber, and extends in parallel with the side wall of the cylindrical electrode. The shield connected to the chamber also serves as the cathode. The shield is installed so as to face the cylindrical electrode via a slight gap to not to contact the cylindrical electrode.

Recently, workpieces to be processed tend to increase the dimension, and the cylindrical electrode also tends to increase the dimension in order to meet a request for improving a process efficiency. In order to reduce the weight increased due to the increase in dimension of the cylindrical electrode, there is a technical trend of thinning the cylindrical electrode. In film treatment process, since obtaining plasma remarkably increases the temperature of the cylindrical electrode, the thinned cylindrical electrode may be deformed by heat, contact the shield. The contact of the cylindrical electrode with the shield, that is, the contact of the electrode which a voltage is applied to with the grounded electrode produces abnormal discharge, making the plasma unstable. Consequently, stable film treatment process may become difficult.

The present disclosure has been made in order to address the above technical problems, and an objective is to provide a highly reliable plasma processing apparatus capable of preventing a contact between a cylindrical electrode and a shield, and also capable of executing stable film treatment process.

### SUMMARY OF THE INVENTION

In order to achieve the above objective, a plasma processing apparatus according to an aspect of the present disclosure includes:

a cylindrical electrode having a first end provided with an opening, and a second end that is a closed end, a process gas being to be introduced in an interior of the cylindrical electrode, and the cylindrical electrode obtaining a plasma process gas upon application of a voltage;

a vacuum container provided with an opening, the second end of the cylindrical electrode being attached to the opening via an insulation material, and the cylindrical electrode being extended in an interior of the vacuum container;

a carrying unit carrying a workpiece to be processed by the process gas to a space below the opening of the cylindrical electrode;

a shield connected to the vacuum container, and covering the cylindrical electrode extended in the interior of the vacuum container via a gap; and

a spacer formed of an insulation material, and installed in a part of the gap between the cylindrical electrode and the shield.

The spacer may be formed in a block shape.

A surface of the spacer facing the cylindrical electrode and a surface of the spacer facing the shield may have an area of 1 to 3 cm².

The spacer may include an inclined part located at a corner of the surface facing the cylindrical electrode and at the opening side of the vacuum container, and inclined toward the shield.

The spacer may be fastened to the shield by a bolt formed of an insulation material.

The spacer maybe installed at a location nearby the first end of the cylindrical electrode.

A plurality of the spacers may be installed at a location nearby the first end of the cylindrical electrode, the second end, a middle portion between the first end and the second end.

The cylindrical electrode and the shield may be each formed in a rectangular cylindrical shape, and a plurality of the spacers may be installed at gaps opposite between the cylindrical electrode and the shield.

According to the present disclosure, by installing the spacer in the gap between the side wall of the cylindrical electrode and the shield, a contact between the cylindrical electrode and the shield is prevented, and thus a highly reliable plasma processing apparatus capable of performing stable film treatment process is provided.

### BRIEF DESCRIPTION OF THE DRAWINGS

FIG. 1 is a plan view illustrating an exemplary structure of a plasma processing apparatus according to an embodiment of the present disclosure;

FIG. 2 is a cross-sectional view taken along a line A-A in FIG. 1;

FIG. 3 is a cross-sectional view taken along a line B-B in FIG. 1, and illustrating a film treatment process unit as viewed from a center of rotation table;

FIG. 4 is an enlarged side view of a spacer;

FIG. 5 is an enlarged front view of the spacer;

FIG. 6 is a diagram illustrating the spacer being attached to a shield;

FIG. 7 is a diagram illustrating another example installation scheme of the spacer; and

FIG. 8 is a diagram illustrating a comparative example in which an insulation member covers the entire gap between a cylindrical electrode and a shield.

### DETAILED DESCRIPTION OF THE EMBODIMENTS

[Structure]

An embodiment of the present disclosure will be explained in detail with reference to the accompanying figures.

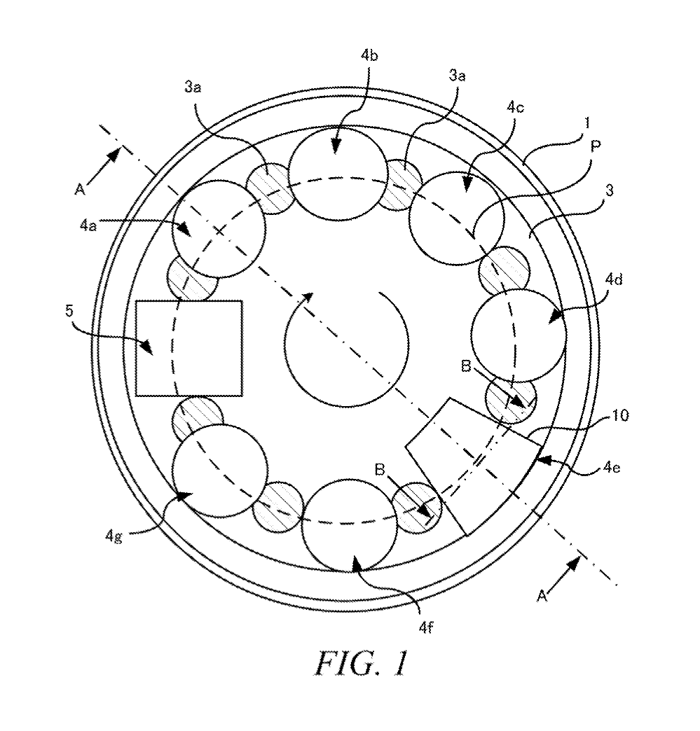

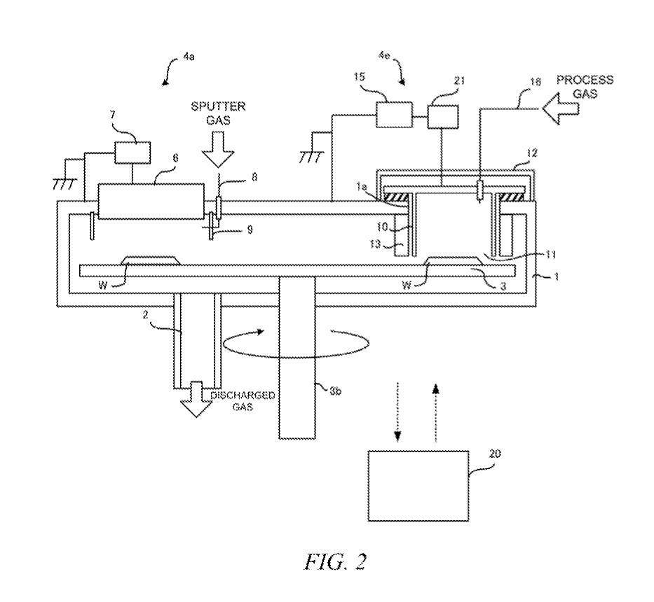

As illustrated in FIGS. 1 and 2, a plasma processing apparatus includes a substantially cylindrical chamber 1. A chamber 1 is provided with a gas discharging unit 2 that is capable of discharging the interior of the chamber 1 to be in a vacuum condition. That is, the chamber 1 serves as a vacuum container. An opening 1a is provided in the upper surface of the chamber 1, and a cylindrical electrode 10 to be explained later is fitted in this opening 1a, and a gas-tight interior of the chamber 1 is maintained. A rotation shaft 3b, which passes through the bottom of the chamber 1 and stands upright in the chamber 1, is provided. A rotation table 3 with a substantially circular shape is attached to the rotation shaft 3b. The rotation shaft 3b is coupled with an unillustrated drive unit. Upon the drive by the drive unit, the rotation table 3 rotates around the rotation shaft 3b.

Since the chamber 1, the rotation table 3, and the rotation shaft 3b serve as a cathode in the plasma processing apparatus, those maybe formed of a conductive metal that has a little electrical resistance. For example, the rotation table 3 may be formed of a stainless-steel plate having a surface to which melted aluminum oxide is applied.

A plurality of holder units 3a that hold respective workpieces W are provided on the upper surface of the rotation table 3. The holder units 3a are provided at equal pitch along the circumferential direction of the rotation table 3. The rotating rotation table 3 rotates to move the workpiece W held by the holder unit 3a in the circumferential direction. In other words, a carrying path P that is the circular movement trajectory of the workpiece W is formed on the surface of the rotation table 3. The holder unit 3a is, for example, a tray on which the workpiece W is placed.

Hereinafter, the term “circumferential direction” means the “circumferential direction of the rotation table 3”, and the term “radial direction” means the “radial direction of the rotation table 3”. In addition, according to this embodiment, an example workpiece W is a tabular substrate, but the type, shape, and material of the workpiece W subjected to the plasma processing are not limited to any particular ones. For example, a curved substrate that has a concavity or convexity at the center may be applied. In addition, a substrate formed of a material containing a conductive material like metal or carbon, an insulation material like glass or rubber, and a semiconductor material like silicon may be applied.

Provided above the rotation table 3 are process units for various processes in the plasma processing apparatus. The process units are installed along the carrying path P for the workpiece W on the surface of the rotation table 3 at a predetermined pitch between each other. The workpiece W held by the holder units 3a is passed through the space below the process units, and has the processes performed.

In the example case illustrated in FIG. 1, seven process units 4a to 4g are installed along the carrying path P on the rotation table 3. In this embodiment, the process units 4a, 4b, 4c, 4d, 4f, and 4g are each a film formation unit that performs film formation on the workpiece W. The process unit 4e is a film treatment process unit that processes the film formed on the workpiece W by the film formation unit. In this embodiment, an explanation will be given of an example case in which the film formation unit performs sputtering. In addition, an explanation will be given of an example case in which the film treatment process unit 4e performs post oxidization. Post oxidization is a process of oxidizing a metal film formed by the film formation unit by introducing oxygen ions, etc., produced by plasma.

A load-lock chamber 5 which carries in the unprocessed workpiece W to the chamber 1 from the exterior, and carries out the processed workpiece W to the exterior is installed between the process unit 4a and the process unit 4g. Note that in this embodiment, the carrying direction of the workpiece W is defined as a clockwise direction from the process unit 4a to the process unit 4g in FIG. 1. Needless to say, this is merely an example, and the carrying direction, the type of the process unit, the installation sequence and the number of the process units are not limited to any particular ones, and can be designed as appropriate.

FIG. 2 illustrates an example structure of the process unit 4a that is the film formation unit. The other film formation units 4b, 4c, 4d, 4f, and 4g may employ the same structure, but other structures are also applicable. As illustrated in FIG. 2, the film formation unit 4a includes a target 6 attached to the internal upper surface of the chamber 1 as a sputtering source. The target 6 is a tabular member formed of a material to be deposited on the workpiece W. The target 6 is placed at a position facing the workpiece W when the workpiece W passes through the space below the film formation unit 4a. The target 6 is connected to a DC power supply 7 that applies the DC voltage to the target 6. In addition, a sputter gas introducing unit 8 that introduces a sputter gas into the chamber 1 is installed to the location near the target which is attached to at the internal upper surface the chamber 1. An example sputter gas is an inactive gas like argon. A partition wall 9 to reduce the flow-out of the plasma is installed around the target 6. In addition, a conventionally well-known power supply, such as a DC pulse power supply or an RF power supply, is applicable.

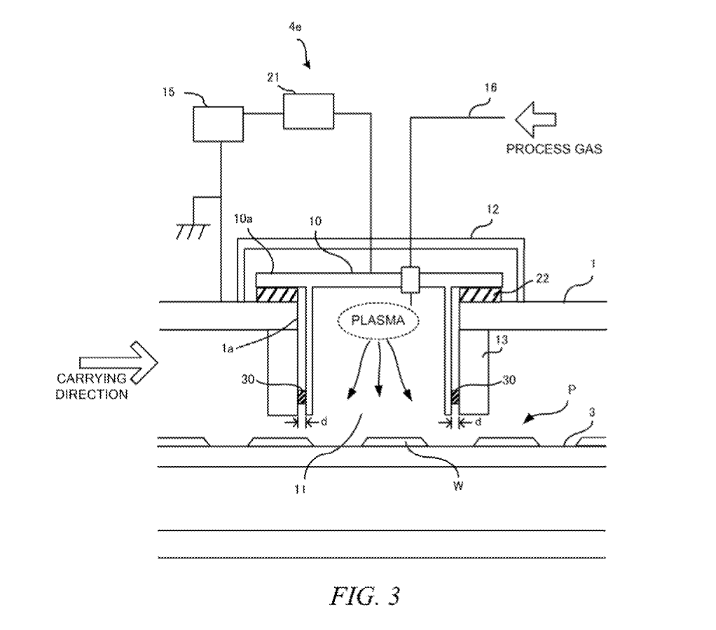

FIGS. 2 and 3 illustrate an example structure of the film treatment process unit 4e. The film treatment process unit 4e includes a cylindrical electrode 10 installed on the internal upper surface of the chamber 1. The cylindrical electrode 10 is formed in a rectangular cylindrical shape, and has an opening 11 in the one end, and the closed other end. The cylindrical electrode 10 has a first end, which is provided with an opening, located at the lower side (hereinafter, referred to as a “lower end”), and has a second end located at the upper side (hereinafter, referred to as an “upper end”). The upper end is attached to the opening 1a formed in the upper surface of the chamber 1 via an insulation material 22. The side wall of the cylindrical electrode 10 extends in the interior of the chamber 1, and the opening 11 located at the lower end faces the rotation table 3. More specifically, the upper end is provided with a flange 10a that spreads outwardly. The insulation material 22 is fastened to the lower surface of the flange 10a and the circumferential edge of the opening 1a of the chamber 1, and thus the gas-tight interior of the chamber 1 is maintained. The insulation member 22 is not limited to any particular material, but may be formed of, for example, a material like polytetrafluoroethylene (PTFE).

The opening 11 of the cylindrical electrode 10 is placed at the location facing the carrying path P formed on the rotation table 3. That is, the rotation table 3 serves as a carrying unit that carries the workpiece W to pass through the location right below the opening 11. In addition, the location right below the opening 11 becomes a passing-through position for the workpiece W.

As illustrated in FIG. 1, when viewed from above, the cylindrical electrode 10 is formed in a sector shape that increases the diameter from the center toward the external side in the radial direction of the rotation table 3. In this case, the sector shape means a shape of a sector plane of a sector. The opening 11 of the cylindrical electrode 10 is also in a sector shape. The speed the workpiece W held on the rotation table 3 passing through below the opening 11 becomes slower toward the center in the radial direction of the rotation table 3, and becomes faster toward the external side. Hence, if the opening 11 is simply in a rectangular or square shape, there is a time difference in the workpiece W passing through right below the opening 11 at the center side in the radial direction and at the external side. By increasing the diameter of the opening 11 from the center toward the external side in the radial direction, a time for the workpiece W passing through right below the opening 11 is kept constant, and thus the plasma process to be explained later can be performed uniformly. However, the opening 11 may be in a rectangular or square shape as long as the passing-through time difference does not affect the quality for final products. The dimension of the cylindrical electrode 10 and the thickness of the side wall of the cylindrical electrode 10 are not limited to any particular ones, but the cylindrical electrode 10 tends to be larger and thinner, and for example, the cylindrical electrode 10 that has a width of 300 to 400 mm in the circumferential direction, a width of 800 mm in the radial direction, and has a thickness of the side wall which is substantially 1 mm may be applied.

As explained above, the cylindrical electrode 10 passes through the opening 1a of the chamber 1, and has a part exposed to the exterior of the chamber 1. The part of the cylindrical electrode 10 exposed to the exterior of the chamber 1 is covered by a housing 12 as illustrated in FIG. 2. The housing 12 maintains the gas-tight internal space of the chamber 1. The part of the cylindrical electrode 10 located inside the chamber 1, that is, the surrounding of the side wall is covered by a shield 13.

The shield 13 is a rectangular cylinder in a sector shape coaxial with the cylindrical electrode 10, and is larger than the cylindrical electrode 10. The shield 13 is connected to the chamber 1. More specifically, the shield 13 stands upright from the circumferential edge of the opening 1a of the chamber 1, extends toward the interior of the chamber 1, and has the lower end located at the same height as the opening 11 of the cylindrical electrode 10. Since the shield 13 serves as the cathode like the chamber 1, the shield 13 may be formed of a conductive metal that has a little electrical resistance. The shield 13 may be formed integrally with the chamber 1, or may be attached thereto using fastening brackets, etc.

The shield 13 is provided so as to stably produce plasma inside the cylindrical electrode 10. Each side walls of the shield 13 is provided so as to extend substantially in parallel with each side walls of the cylindrical electrode 10 via a predetermined gap d. When the gap d is too wide, the electrostatic capacitance becomes small, and the produced plasma inside the cylindrical electrode 10 enters the gap d. Hence, it is desirable that the gap d is as small as possible. However, when the gap d is too narrow, the electrostatic capacitance between the cylindrical electrode 10 and the shield 13 becomes large, which is not preferable. It is desirable that the size of the gap d should be set as appropriate in accordance with the necessary electrostatic capacitance for producing the plasma, and for example, the gap d may be set to 7 mm. Although FIG. 3 illustrates only two respective side walls extending in the radial direction of the shield 13 and of the cylindrical electrode 10, the gap d that has the same size as that of the side wall in the radial direction is also provided between the two respective side walls in the circumferential direction of the shield 13 and of the cylindrical electrode 10.

A process gas introducing unit 16 is connected to the cylindrical electrode 10, and the process gas is introduced in the cylindrical electrode 10 from an external process gas supply source via the process gas introducing unit 16. The process gas can be changed as appropriate in accordance with the purpose of film treatment process. When, for example, etching is to be performed, an etching gas that is an inactive gas like argon is applicable. When oxidization or post oxidization is to be performed, oxygen is applicable. When nitridation is to be performed, nitrogen is applicable.

The cylindrical electrode 10 is connected to an RF power supply 15 for applying a high-frequency voltage. A matching box 21 that is a matching circuit is connected in series to the output side of the RF power supply 15. The RF power supply 15 is also connected to the chamber 1. When a voltage is applied from the RF power supply 15, the cylindrical electrode 10 serves as an anode, while the chamber 1, the shield 13, and the rotation table 3 serve as a cathode. The matching box 21 matches impedances between the input side and the output side, and stabilizes the plasma discharge. Note that the chamber 1 and the rotation table 3 are grounded. The shield 13 connected to the chamber 1 is also grounded. The RF power supply 15 and the process gas introducing unit 16 are both connected to the cylindrical electrode 10 via a through-hole formed in the housing 12.

When the process gas that is an oxygen gas is introduced to the interior of the cylindrical electrode 10 via the process gas introducing unit 16, and a high-frequency voltage is applied from the RF power supply 15 to the cylindrical electrode 10, the plasma oxygen gas is obtained, and thus electrons, ions, and radicals, etc., are produced. When the plasma oxygen gas is obtained, the interior of the cylindrical electrode 10 becomes a high temperature. As explained above, since the cylindrical electrode 10 tends to increase the dimension and decrease the thickness, the cylindrical electrode 10 maybe deflected or deformed by heat. As explained above, since the gap d between the cylindrical electrode 10 and the shield 13 is small, when the cylindrical electrode 10 is deformed, there is a possibility that the cylindrical electrode 10 contacts the shield 13.

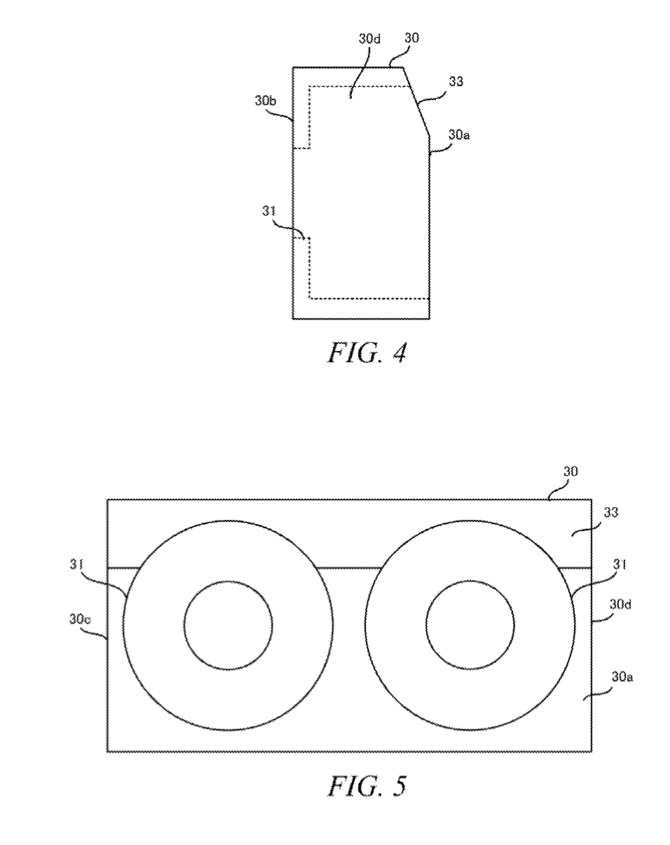

According to the embodiment of the present disclosure, a spacer 30 is installed in the gap d between the cylindrical electrode 10 and the shield 13. Even if the cylindrical electrode 10 is deformed, since the spacer 30 suppress the displacement of the cylindrical electrode 10, a contact between the cylindrical electrode 10 and the shield 13 is prevented. FIGS. 4 to 6 are each an enlarged view of the spacer 30. The spacer 30 is a cuboid block. In order to ensure the insulation between the anode and the cathode, the spacer 30 may be formed of an insulation material. The spacer 30 may be formed of PTFE like the insulation member 22.

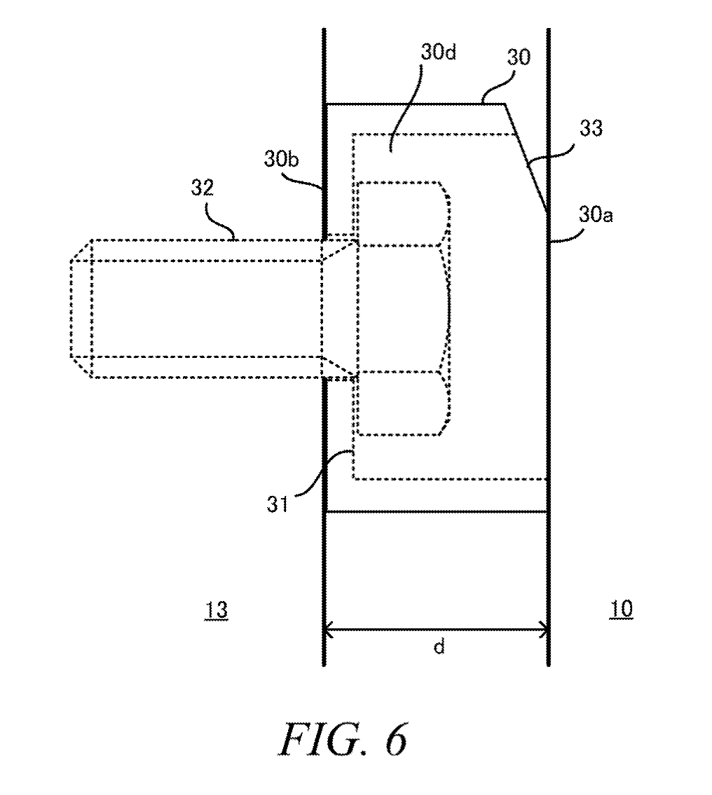

The spacer 30 includes an upper surface and a lower surface in parallel to each other facing the upper surface of the chamber 1 and the bottom surface thereof, respectively. The spacer 30 further includes four side surfaces 30a, 30b, 30c, 30d that connect the upper surface with the lower surface. Bolt holes 31 are provided so as to pass through the side surface 30a facing the cylindrical electrode 10 and the side surface 30b facing the shield 13. The bolt hole 31 has a dimension that enables the head of a bolt 32 to enter at the cylindrical-electrode-10 side, but decreases the diameter at the shield-13 side, and becomes the dimension that enables only the thread part of the bolt 32 to pass through. In the illustrated example, two bolt holes 31 are provided in parallel with each other, but the number of bolt holes 31 and the locations thereof are not limited to those of the illustrated example, and may be designed as appropriate. As illustrated in FIG. 6, the spacer 30 is fastened to the shield 13 by the bolts 32 inserted in the respective bolt holes 31. The bolt 32 may be formed of an insulation material, such as PEEK or PTFE.

The dimension of the spacer 30 can be designed as appropriate, but downsizing is desirable so that the spacer 30 formed of the insulation material does not affect the electrostatic capacitance between the anode and the cathode. For example, the area of the side surface 30a facing the cylindrical electrode 10 and the area of the side surface 30b facing the shield 13 may be 1 to 3 cm².

The width of the side surface 30c, 30d which is orthogonal to each of the side surfaces 30a, 30b, and which connects each of the side surfaces 30a, 30b may be equal to or slightly narrower than the gap d between the cylindrical electrode 10 and the shield 13 to fit in the gap d therebetween. When, for example, the gap d is 7 mm, the width of the side surface 30c, 30d may be 6 mm.

The side surface 30a that faces the cylindrical electrode 10 is chamfered so as to eliminate the corner located at the opening-1a side of the chamber 1, and an inclined part 33 inclined toward the shield 13 is provided. The inclination angle may be set as appropriate, but, for example, may be 30 degrees relative to the side surface 30a. When the spacer 30 is to be attached, with the cylindrical electrode 10 being detached from the opening 1a of the chamber 1, the spacer 30 is attached to the shield 13 by the bolts 32. Subsequently, the cylindrical electrode 10 is inserted in the opening 1a. As explained above, since the spacer 30 is formed in a dimension to be fitted in the gap d, the cylindrical electrode 10 can be inserted smoothly by the inclined part 33.

In the example case illustrated in FIG. 3, the two spacers 30 are installed in the respective gaps d between the two side walls of the rectangular cylindrical shield 13 and the cylindrical electrode 10 along the radial direction. That is, the two spacers 30 are installed in gaps d which faces with each other in a rotation direction. By respectively installing the two spacers 30 in the facing gaps d, the stable gap d can be maintained. In addition, the two spacers 30 are installed at the locations nearby the lower end of the cylindrical electrode 10. As for the cylindrical electrode 10, the portion near the lower end that is an opened end may be likely to be deformed in comparison with the portion nearby the upper end attached to the chamber 1. Since the spacer 30 is installed at the location nearby the lower end, the portion nearby the lower end of the cylindrical electrode 10 that is likely to be deformed is prevented from contacting the shield 13.

However, the example illustrated in FIG. 3 is merely an example, and the number of installed spacers 30 and the installation locations thereof are not limited to those of the above example. Even if the cylindrical electrode 10 is deformed, the installation location and the number of installed spacers 30 can be designed as appropriate as long as the gap d between the shield 13 and the cylindrical electrode 10 is maintained to prevent a contact, and the increase in electrostatic capacitance by the installed spacer 30 does not affect the control by the matching box 21.

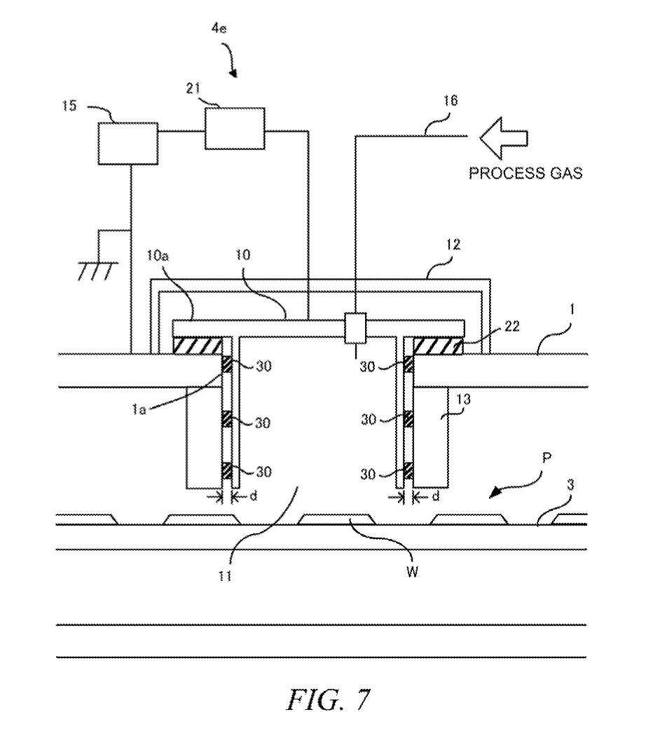

For example, as illustrated in FIG. 7, in addition to the location nearby the lower end, the spacers 30 may be installed at the location nearby the upper end, and nearby the middle portion between the upper and lower ends to maintain the stable gap d as a whole. Needless to say, it is unnecessary to install the spacers 30 at all three locations, and the spacer 30 maybe installed at, for example, only the location nearby the upper end or only the location nearby the middle portion only. The installation pitch of the spacer 30 may be equal. Alternatively, the installation pitch may be not equal, and for example, a larger number of spacers 30 may be installed at the locations nearby the lower end.

In addition, FIGS. 3, 7 illustrate an example in which the spacers 30 are installed in the respective gaps d between the two side walls of the rectangular cylindrical shield 13 and the cylindrical electrode 10 along the radial direction, but the spacers 30 may be installed in the respective gaps between the two side walls along the circumferential direction. Needless to say, the spacers 30 may be installed in both the radial direction and the circumferential direction. Alternatively, instead of installing the spacers 30 in the respective gaps d at the opposite sides in the same direction, the spacers 30 may be installed in the one gap d in the radial direction and in the one gap d in the circumferential direction.

The plasma processing apparatus further includes a control unit 20. The control unit 20 includes an arithmetic processing unit, such as a PLC or a CPU. The control unit 20 controls, for example, an introduction of the sputter gas and the process gas into the chamber 1, and discharging therefrom, the DC power supply 7 and an RF power supply 15, and the rotation speed of the rotation table 3.

[Action and Effect]

An action of the plasma processing apparatus according to this embodiment, and the effect to be achieved by the spacer 30 will be explained. The unprocessed workpiece W is carried into the chamber 1 from the load-lock chamber 5. The carried work-piece W is held by the holder unit 3a on the rotation table 3. The interior of the chamber 1 is maintained in the vacuum condition by gas discharging through the gas discharging unit 2. By driving the rotation table 3, the workpiece W is carried along the carrying path P, and is caused to pass through below each process unit 4a to 4g.

As for the film formation unit 4a, the sputter gas is introduced from the sputter gas introducing unit 8, and the DC voltage is applied to the sputter source from the DC power supply 7. Upon application of the DC voltage, the plasma sputter gas is obtained, and ions are produced. When the produced ions collide with the target 6, the material particles of the target 6 are beaten out. The beaten-out material particles are deposited on the workpiece W that passes through below the film formation unit 4a, and thus a thin film is formed on the workpiece W. As for the other film formation units 4b, 4c, 4d, 4f, and 4g, the film formation is executed through the same scheme. However, it is unnecessary to perform film formation at each of all film formation units. As an example, an Si film is formed on the workpiece W by DC sputtering.

The workpiece W having undergone the film formation by each film formation unit 4a to 4d is subsequently carried through the carrying path P by the rotation table 3, and as for the film treatment process unit 4e, this workpiece W passes through the location below the opening 11 of the cylindrical electrode 10, that is, a film treatment process position. As explained above, according to this embodiment, an explanation will be given of an example case in which the film treatment process unit 4e performs post oxidization. In the film process unit 4e, the process gas that is an oxygen gas is introduced from the process gas introducing unit 16 to the cylindrical electrode 10, and a high-frequency voltage is applied from the RF power supply 15 to the cylindrical electrode 10. Upon application of the high-frequency voltage, the plasma oxygen gas is obtained, and electrons, ions, and radicals, etc., are produced. The plasma flows from the opening 11 of the cylindrical electrode 10 that is the anode to the rotation table 3 that is the cathode. When the ions in the plasma collide with the thin film formed on the workpiece W passing through below the opening 11, post oxidization is performed on the thin film.

As explained above, the RF power supply 15 is connected to the matching box 21. The matching box 21 matches the impedance of the output side and the input side, and maximizes the current flowing toward the cathode, thereby enabling a stable plasma discharge. When, however, the cylindrical electrode 10 is deflected and deformed by heat generated in the plasma process, and contacts the shield 13, an abnormal discharge may occur.

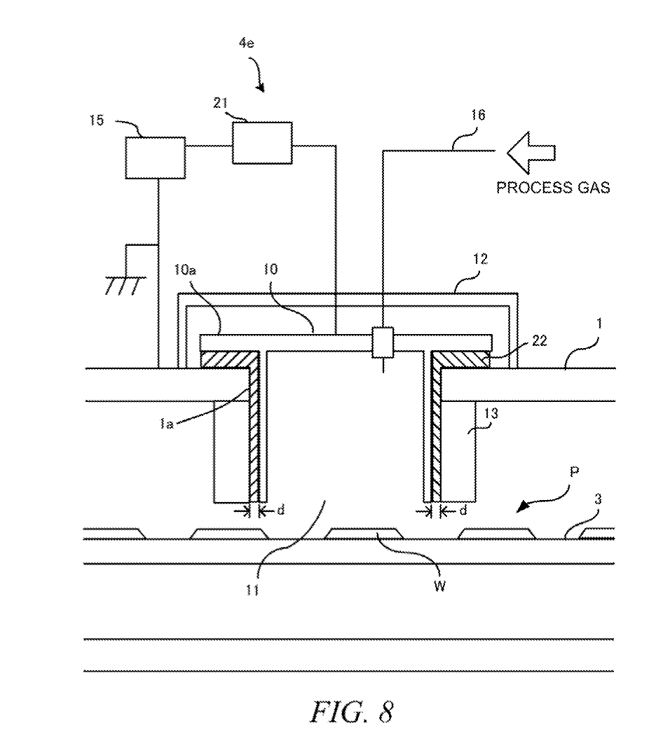

In this embodiment, since the spacer 30 is installed in the gap d between the shield 13 and the cylindrical electrode 10, even if the cylindrical electrode 10 is deformed, a contact with the shield 13 is preventable. In this case, when the purpose is simply to prevent the cylindrical electrode 10 from contacting the shield 13, as illustrated in FIG. 8, the insulation member 22 present between the flange 10a of the upper end of the cylindrical electrode 10 and the circumferential edge of the opening 1a of the chamber 1 may be further extended so as to cover the entire gap d between the cylindrical electrode 10 and the shield 13. When, however, the entire gap d between the cylindrical electrode 10 and the shield 13 is occupied with the insulation member 22, the electrostatic capacitance between the anode and the cathode remarkably increases.

The matching box 21 controls the impedance based on the preset electrostatic capacitance between the anode and the cathode. With respect to already-installed plasma processing apparatuses, when the insulation member 22 is replaced with the insulation member 22 that occupies the entire gap d, it is necessary to reset the matching box 21 based on the increased electrostatic capacitance, which is not user friendly.

Hence, according to this embodiment, the spacer 30 formed in a block shape is installed in the gap d between the cylindrical electrode 10 and the shield 13 so as not to largely affect the electrostatic capacitance between the anode and the cathode. The spacer 30 is installed in a part of the gap d. Hence, in comparison with the insulation member 22 as illustrated in FIG. 8 which occupies the entire gap d, an increase rate in electrostatic capacitance is reduced. Even if the electrostatic capacitance slightly increases by the spacer 30, it is unnecessary to reset the matching box 21 as long as the electrostatic capacitance is within the allowable range for the control by the matching box 21. When the increase rate in electrostatic capacitance is substantially less than ±1%, it is known that stable plasma is maintainable without a reset of the matching box 21.

The increase rate in electrostatic capacitance is compared and examined for a case in which the insulation member 22 covers the entire gap d between the cylindrical electrode 10 and the shield 13 as illustrated in FIG. 8, and for a case in which the spacer 30 is installed according to this embodiment.

According to the structure illustrated in FIG. 8, when the insulation member 22 is formed of PTFE, since the gap d is replaced with the PTFE that has the relative permittivity of 2.1, in comparison with a case in which the gap d is fully empty, the electrostatic capacitance becomes substantially twice as large, and an increase rate in electrostatic capacitance is substantially 100%. That is, when the structure illustrated in FIG. 8 is employed, the increase in the electrostatic capacitance is far beyond the allowable range for the control by the matching box 21. Hence, it is necessary to reset the matching box 21.

An increase rate R [%] in electrostatic capacitance according to the structure of this embodiment in which the spacer 30 is installed in the gap d is obtainable as follows.

In a capacitor formed of an anode and a cathode that are parallel plates with each other, when an inter-plate distance is k [m], and an area of each parallel plate is S [m²], an electrostatic capacitance C [F] is obtainable from the following formula (1).

$$\begin{matrix}[ Formula 1 ] & \\ C = {ɛ}_{0} {ɛ}_{r} \frac{S}{k} & ( 1 )\end{matrix}$$

where ε₀ is an electric permittivity in vacuum, and is 8.85×10⁻¹² [F/m], and εᵣ is a relative permittivity of a dielectric body.

When the spacer 30 of this embodiment is formed of PTFE, εᵣis 2.1. Since an increase amount of an electrostatic capacitance Cₚ per a spacer 30 is obtainable by subtracting the electrostatic capacitance of a space replaced with the single spacer 30 from the electrostatic capacitance of the single spacer 30, Cₚ is obtainable from the following formula (2).

$$\begin{matrix}[ Formula 2 ] & \\ {C}_{p} = ( {ɛ}_{r} - 1 ) {ɛ}_{0} \frac{{S}_{p}}{d} & ( 2 )\end{matrix}$$

where Sₚ is an area [m²] of the spacer 30 facing the cylindrical electrode 10. The inter-plate distance k [m] in the formula (1) corresponds to the dimension of the gap d. When Sₚ=6×10⁻⁴ [m²]=6 [cm²], and d=7×10⁻³ [m]=7 [mm] are substituted in the above formula (2) , the value of Cₚ becomes 8.35×10⁻¹³ [F].

The increase rate R [%] in electrostatic capacitance upon application of the spacer 30 is obtainable from the following formula (3) when the electrostatic capacitance of the cylindrical electrode 10 that has no spacer 30 is C₀ [F].

$$\begin{matrix}[ Formula 3 ] & \\ R = \frac{{C}_{p} \times n}{{C}_{0}} \times 100 & ( 3 )\end{matrix}$$

where n is the number of installed spacers 30. When the number of installed spacers 30 is, for example, nine, C₀=7.6×10⁻¹⁰ [F], and n=9 are substituted in the formula (3) , and the increase rate R becomes substantially 0.99[%].

That is, even if the nine spacers 30 are installed, in comparison with a case in which no spacer 30 is installed, the increase rate in electrostatic capacitance is less than 1%. Hence, such an increase in electrostatic capacitance does not affect the control by the matching box 21, and the stable plasma is maintainable without a re-set.

[Effect]

As explained above, the plasma processing apparatus according to this embodiment includes a cylindrical electrode 10 which has a lower end that is an end provided with the opening 11, has an upper end that is a closed other end, has the interior in which the process gas is introduced and obtains the plasma process gas upon application of the voltage, and the chamber 1 that is a vacuum container provided with the opening 1a. The cylindrical electrode 10 that has the upper end attached to the opening 1a of the chamber 1 via the insulation member 22 is extended in the chamber 1. In addition, this plasma processing apparatus includes the rotation table 3 that is a carrying unit which carries the workpiece W to be processed by the process gas to the location right below the opening 11 of the cylindrical electrode 10, the shield 13 that covers the cylindrical electrode 10 extended in the vacuum container via the gap d, and the spacers 30 which are each installed at a part of the gap d between the cylindrical electrode 10 and the shield 13, and formed of the insulation material.

In the film treatment process, since the produced plasma remarkably increases the temperature, the cylindrical electrode 10 is deformed by heat, and may contact the shield 13. By installing the spacer 30 in the gap d between the side wall of the cylindrical electrode 10 and the shield 13, the contact of the cylindrical electrode 10 with the shield 13 is prevented, enabling a stable film treatment process. In addition, by installing the spacer 30 not in the entire gap d but in a part thereof, the installed spacer 30 does not greatly affect the electrostatic capacitance between the anode and the cathode, even if the spacer 30 is applied to already-installed plasma processing apparatuses, it is unnecessary to set up the matching box 21 again, resulting in a high user friendliness.

The spacer 30 may be in a block shape. This facilitates fitting and attachment in the narrow gap d between the side wall of the cylindrical electrode 10 and the shield 13.

The side surface 30a of the spacer 30 facing the cylindrical electrode 10, and the side surface 30b facing the shield 13 may have an area of 1 to 3 cm². By downsizing the spacer 30, a change in electrostatic capacitance between the anode and the cathode can be reduced. Hence, even if the spacer 30 is applied to already-installed plasma processing apparatuses, it is unnecessary to set up the matching box 21 again, resulting in a high user friendliness.

The spacer 30 may have the inclined part 33 which is located at the corner of the side surface 30a at the opening-1a side of the chamber 1, and which is inclined toward the shield 13. Since the gap d between the cylindrical electrode 10 and the shield 13 is narrow, when the cylindrical electrode 10 is inserted into the opening 1a after the spacer 30 is installed, the cylindrical electrode 10 may interfere with the spacer 30. In this case, since the corner of the spacer 30 is chamfered, such an interference is prevented, enabling a smooth insertion of the cylindrical electrode 10. This improves the assembling efficiency.

The spacer 30 may be fastened to the shield 13 by the bolts 32 formed of an insulation material. Since the bolts 32 that fasten the spacer 30 are also formed of the insulation material, the insulation between the anode and the cathode is still maintainable.

The spacer 30 maybe installed at the location nearby the lower end of the cylindrical electrode 10 where the opening 11 is formed. By installing the spacer 30 at the location nearby the lower end of the cylindrical electrode 10 which is likely to be deformed, a contact with the shield 13 is effectively prevented.

The spacers 30 may be installed at the location nearby the lower end of the cylindrical electrode 10 where the opening 11 is formed, the location nearby the upper end, and the location nearby the middle portion between the upper end and the lower end. By installing the distributed spacers 30, the gap d between the cylindrical electrode 10 and the shield 13 is stably maintainable as a whole.

The cylindrical electrode 10 and the shield 13 may be formed in a rectangular cylindrical shape, and the spacers 30 may be installed at each gap d, which faces with each other, between the cylindrical electrode 10 and the shield 13. By installing the two spacers 30 in the respective opposing gaps d, the gaps d are stably maintained.

[Other Embodiments]

(1) The present disclosure is not limited to the above embodiment. For example, in the above embodiment, post oxidization is performed as film treatment process, but etching or nitridation may be performed. In the case of etching, the film treatment process unit 4e may introduce an argon gas, and in the case of nitridation, the film treatment process unit 4e may introduce a nitrogen gas.

(2) The shape of the rotation table 2 and that of the chamber 1 in which each process unit is installed, the type of process unit, and the installation scheme thereof are not limited to any particular ones, and can be changed as appropriate in accordance with the type of the workpiece W, and the installation environment.

The embodiment of the present disclosure and the modified examples of respective components have been explained above, but those embodiment and modified examples of respective components are merely presented as examples, and are not intended to limit the scope of the present disclosure. The above novel embodiment and modified examples can be carried out in other various forms, and various omissions, replacements, and modifications can be made thereto without departing from the scope of the present disclosure. Such embodiments and modified forms thereof are within the scope of the present disclosure, and also within the scope of the invention as recited in the appended claims.

What is claimed is:

1. A plasma processing apparatus comprising:
a cylindrical electrode having a first end provided with an opening, and a second end that is a closed end, a process gas being to be introduced in an interior of the cylindrical electrode, and the cylindrical electrode obtaining a plasma process gas upon application of a voltage;
a vacuum container provided with an opening, the second end of the cylindrical electrode being attached to the opening via an insulation material, and the cylindrical electrode being extended in an interior of the vacuum container;
a carrying unit carrying a workpiece to be processed by the process gas to a space below the opening of the cylindrical electrode;
a shield connected to the vacuum container, and covering the cylindrical electrode extended in the interior of the vacuum container via a gap; and
a spacer formed of an insulation material, and installed in a part of the gap between the cylindrical electrode and the shield.

2. The plasma processing apparatus according to claim 1, wherein the spacer is formed in a block shape.

3. The plasma processing apparatus according to claim 2, wherein a surface of the spacer facing the cylindrical electrode and a surface of the spacer facing the shield have an area of 1 to 3 cm².

4. The plasma processing apparatus according to claim 2, wherein the spacer comprises an inclined part located at a corner of the surface facing the cylindrical electrode and at the opening side of the vacuum container, and inclined toward the shield.

5. The plasma processing apparatus according to claim 3, wherein the spacer comprises an inclined part located at a corner of the surface facing the cylindrical electrode and at the opening side of the vacuum container, and inclined toward the shield.

6. The plasma processing apparatus according to claim 1, wherein the spacer is fastened to the shield by a bolt formed of an insulation material.

7. The plasma processing apparatus according to claim 1, wherein the spacer is installed at a location nearby the first end of the cylindrical electrode.

8. The plasma processing apparatus according to claim 2, wherein the spacer is installed at a location nearby the first end of the cylindrical electrode.

9. The plasma processing apparatus according to claim 1, wherein a plurality of the spacers is installed at a location nearby the first end of the cylindrical electrode, a location nearby the second end, and a location nearby a middle portion between the first end and the second end.

10. The plasma processing apparatus according to claim 2, wherein a plurality of the spacers is installed at a location nearby the first end of the cylindrical electrode, a location nearby the second end, and a location nearby a middle portion between the first end and the second end.

11. The plasma processing apparatus according to claim 1, wherein:
the cylindrical electrode and the shield are each formed in a rectangular cylindrical shape; and
a plurality of the spacers is installed at respective gaps at opposite sides between the cylindrical electrode and the shield.

12. The plasma processing apparatus according to claim 2, wherein:
the cylindrical electrode and the shield are each formed in a rectangular cylindrical shape; and
a plurality of the spacers is installed at respective gaps at opposite sides between the cylindrical electrode and the shield.
